(19) United States
(12) Patent Application Publication
(10) Pub. No.: US 2013/0258095 A1
(43) Pub. Date: Oct. 3, 2013

(54) OPTICAL APPARATUS, MEASURING APPARATUS, LITHOGRAPHY APPARATUS, AND METHOD OF MANUFACTURING ARTICLE

(71) Applicant: CANON KABUSHIKI KAISHA, Tokyo (JP)

(72) Inventors: Toshihiko Nishida, Utsunomiya-shi (JP); Wataru Yamaguchi, Utsunomiya-shi (JP)

(73) Assignee: CANON KABUSHIKI KAISHA, Tokyo (JP)

(21) Appl. No.: 13/835,493

(22) Filed: Mar. 15, 2013

(30) Foreign Application Priority Data
Apr. 3, 2012 (JP) 2012-084701

(51) Int. Cl. G01B 11/14; G03F 7/20

(52) U.S. Cl. CPC G01B 11/14; G03F 7/70133
USPC 348/95; 355/67

(57) ABSTRACT

The present invention provides an optical apparatus which detects an image of a mark on a substrate, the apparatus including an optical system configured to form an image of the mark, a detector configured to detect the image, wherein the optical system includes an aperture stop, an aperture, corresponding to a first field of view and a second field of view of the detector, being formed in the aperture stop, a light-shielding member, and a driving mechanism configured to position the light-shielding member so that one of the first field of view and the second field of view is valid, and a part of the other is invalid.

### BACKGROUND OF THE INVENTION

1. Field of the Invention

The present invention relates to an optical apparatus, a measuring apparatus, a lithography apparatus, and a method of manufacturing an article.

2. Description of the Related Art

In recent years, with an increase in packing density and miniaturization of semiconductor integrated circuits, the line width of a circuit pattern has become very small, so further miniaturization of a pattern (resist pattern) formed (drawn) on a substrate is required in a lithography process. As techniques which achieve such pattern miniaturization, an exposure apparatus (EUV exposure apparatus) which uses EUV light (wavelength: about several to 15 nanometers) with a wavelength shorter than that of ultraviolet rays, and a drawing apparatus (charged particle beam drawing apparatus) which performs drawing on a substrate with a charged particle beam are known.

An exposure apparatus performs pattern exposure while a pattern is overlaid on each shot already formed on a substrate. Hence, to overlay a fine pattern on each shot, it is necessary to perform position measurement of the substrate (shot) with high accuracy. The position measurement can generally be done by detecting alignment marks on the substrate.

Japanese Patent Laid-Open No. 2004-228327 proposes a detection apparatus including a plurality of line sensors, and a plurality of optical systems (optical paths) for guiding (forming) images of X and Y alignment marks to the plurality of line sensors, respectively, to detect these alignment marks.

The detection apparatus detects each alignment mark by switching between an X optical system and X sensor for detecting the X alignment mark, and a Y optical system and Y sensor for detecting the Y alignment mark. Also, in each of the X and Y optical systems, a field stop is arranged (fixed) on a plane conjugate to an image of the alignment mark, and reduces light (stray light) other than light from the alignment mark incident on the sensor.

However, as described above, the conventional detection apparatus requires a plurality of sensors, and a plurality of optical systems (optical paths) corresponding to them to detect the alignment marks, and is therefore disadvantageous in terms of reducing the required space.

### SUMMARY OF THE INVENTION

The present invention provides, for example, an optical apparatus advantageous in terms of reduction of stray light and reduction of required space therefore.

According to one aspect of the present invention, there is provided an optical apparatus which detects an image of a mark on a substrate, the apparatus including an optical system configured to form an image of the mark, a detector configured to detect the image, wherein the optical system includes an aperture stop, an aperture, corresponding to a first field of view and a second field of view of the detector, being formed in the aperture stop, a light-shielding member, and a driving mechanism configured to position the light-shielding member so that one of the first field of view and the second field of view is valid, and a part of the other is invalid.

Further features of the present invention will become apparent from the following description of exemplary embodiments with reference to the attached drawings.

### BRIEF DESCRIPTION OF THE DRAWINGS

FIGS. 1A to 1D are views showing the configuration of an optical device according to an aspect of the present invention.

FIGS. 2A to 2C are views showing the configuration of an optical device capable of switching between the X and Y fields of view.

FIG. 3 is a view showing the configuration of a position detection apparatus according to an aspect of the present invention.

FIG. 4 is a view showing the configuration of an exposure apparatus to which the position detection apparatus shown in FIG. 3 is applied.

FIG. 5 is a view showing the configuration of a drawing apparatus to which the position detection apparatus shown in FIG. 3 is applied.

FIG. 6 is a flowchart for explaining a drawing process by the drawing apparatus shown in FIG. 5.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

### First Embodiment

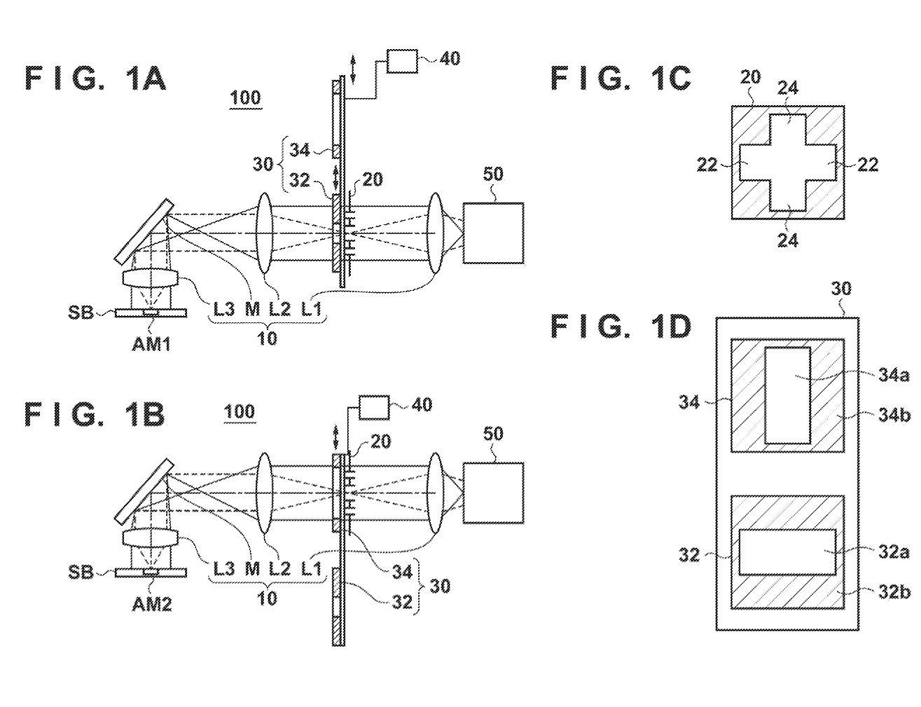

FIGS. 1A to 1D are views showing the configuration of an optical device (optical apparatus) 100 according to an aspect of the present invention. In this embodiment, the optical device 100 is actually used as a device for obtaining images of marks such as alignment marks on a substrate. The optical device 100 includes an imaging optical system 10, field stop 20, light-shielding plate (light-shielding member) 30, driving unit (driving mechanism) 40, and detection unit (detector) 50. The optical device 100 also includes, for example, a light source, and an illumination optical system which illuminates the object plane of the imaging optical system 10 with light from the light source. In this embodiment, the optical device 100 is accommodated in, for example, a vacuum chamber, and the imaging optical system 10, field stop 20, light-shielding plate 30, driving unit 40, and detection unit 50 are arranged under a vacuum environment with a pressure as high as about 10⁻⁴ to 10⁻⁵ Pa. The imaging optical system 10 guides light beams from alignment marks AM1 and AM2 formed on a substrate SB arranged on the object plane of the imaging optical system 10 to the detection unit 50, that is, forms an image of light from this object plane on the detection surface of the detection unit 50. In this embodiment, the imaging optical system 10 includes lenses L1 and L2, mirror M, and objective lens L3. The field stop 20 is arranged in the imaging optical system 10. The field stop 20 is fixed to a plane (to be referred to as a “conjugate plane” hereinafter) conjugate to the imaging plane of the imaging optical system 10 (that is, the detection surface of the detection unit 50) and, more specifically, the conjugate plane in the imaging optical system 10 in this embodiment, and defines the field of view on the imaging plane of the imaging optical system 10. The light-shielding plate 30 is arranged on or in the vicinity of the conjugate plane in the imaging optical system 10 and, more specifically, on the side of the object plane of the imaging optical system 10 with respect to the field stop 20 in this embodiment, and partially shields light that enters the field stop 20. The driving unit 40 is implemented by, for example, an actuator or a motor, and drives the light-shielding plate 30. In this embodiment, the driving unit 40 drives the light-shielding plate 30 in a direction perpendicular to the optical axis of the imaging optical system 10. Also, the driving unit 40 has a configuration suitable for use under a vacuum environment. The driving unit 40 is formed by, for example, a member (material) that outgases less, an adhesive, or a lubricant, or has a configuration that generates less heat. The detection unit 50 includes a detection surface formed by a plurality of pixels, and is implemented by an area sensor such as a CCD sensor or a CMOS sensor. The detection unit 50 detects (obtains) images of the alignment marks AM1 and AM2.

In the optical device 100, light from a light source (not shown) illuminates the alignment mark AM1 or AM2 on the substrate SB via an illumination optical system (not shown). The light from the alignment mark AM1 or AM2 passes through the objective lens L3, is reflected by the mirror M, and enters the lens L2. The light focused by the lens L2 passes through the light-shielding plate 30 and field stop 20, and enters the detection unit 50 via the lens L1. As described above, the field stop 20 and light-shielding plate 30 are arranged on or in the vicinity of the conjugate plane in the imaging optical system 10, so their positional relationship in the imaging optical system 10 is nearly conjugate to the imaging plane of the imaging optical system 10. Hence, the field of view (field-of-view region) to be defined on the imaging plane of the imaging optical system 10 can be changed using the field stop 20 and light-shielding plate 30.

In the optical device 100, the field of view is switched using the field stop 20 including X- and Y-field-of-view openings, and the light-shielding plate 30 including opening regions which pass light beams corresponding to the X and Y fields of view, respectively, and light-shielding regions which shield light other than these light beams. FIG. 1A shows the optical device 100 while the X field of view is set on the imaging plane of the imaging optical system 10 to detect an image of the alignment mark AM1 serving as an X alignment mark (first mark). FIG. 1B shows the optical device 100 while the Y field of view is set on the imaging plane of the imaging optical system 10 to detect an image of the alignment mark AM2 serving as a Y alignment mark (a second mark different from the first mark).

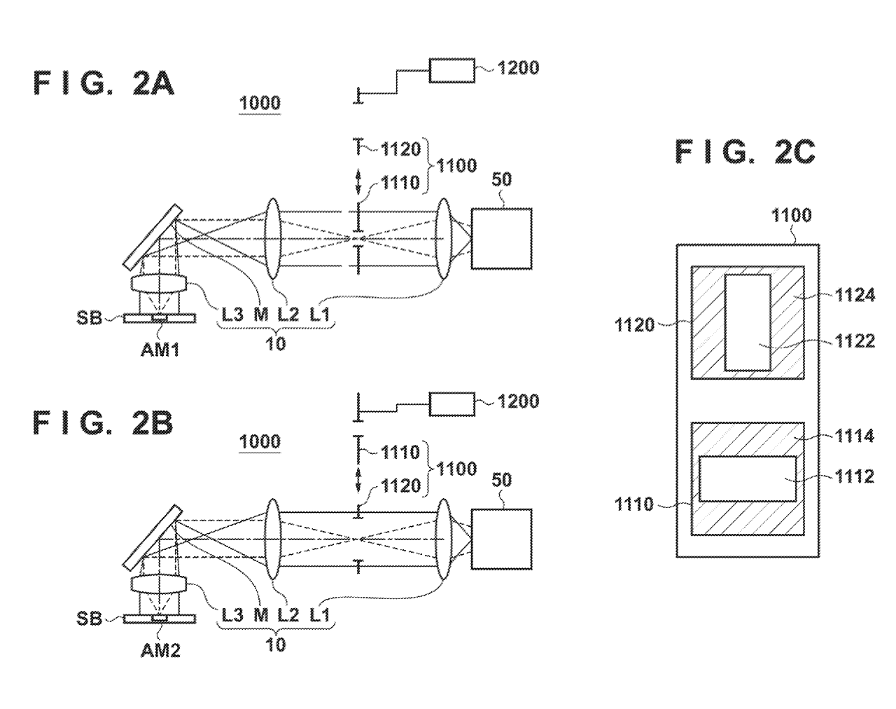

Before a detailed description of, for example, the field stop 20 and light-shielding plate 30, an example of an optical device 1000 capable of switching between the X and Y fields of view with a simple configuration will be explained with reference to FIGS. 2A to 2C. FIG. 2A shows the optical device 1000 while the X field of view is set on the imaging plane of the imaging optical system 10 to detect the alignment mark AM1. FIG. 2B shows the optical device 1000 while the Y field of view is set on the imaging plane of the imaging optical system 10 to detect the alignment mark AM2. Like the optical device 100, the optical device 1000 is accommodated in, for example, a vacuum chamber, and an imaging optical system 10, a field stop 1100, and a driving unit 1200 are arranged under a vacuum environment.

Unlike the optical device 100, the optical device 1000 includes no light-shielding plate 30, and includes the field stop 1100 in place of a field stop 20. Also, unlike the optical device 100, the optical device 1000 includes a driving unit 1200 which drives the field stop 1100, in place of a driving unit 40 which drives a light-shielding plate 30.

In the optical device 1000, light from a light source (not shown) illuminates the alignment mark AM1 or AM2 on the substrate SB via an illumination optical system (not shown). The light from the alignment mark AM1 or AM2 passes through the objective lens L3, is reflected by the mirror M, and enters the lens L2. The light focused by the lens L2 passes through the field stop 1100, and enters the detection unit 50 via the lens L1.

In switching the field of view in the optical device 1000, the driving unit 1200 drives the field stop 1100 to position an X-field-of-view region 1110 for the X field of view or a Y-field-of-view region 1120 for the Y field of view on the optical axis of the imaging optical system 10, as shown in FIGS. 2A and 2B.

FIG. 2C is a view showing the configuration of the field stop 1100 of the optical device 1000. The field stop 1100 includes the X-field-of-view region 1110 including an opening portion 1112 and light-shielding portion 1114 which define the X field of view on the imaging plane of the imaging optical system 10, and the Y-field-of-view region 1120 including an opening portion 1122 and light-shielding portion 1124 which define the Y field of view on the imaging plane of the imaging optical system 10. Hence, the field of view to be defined on the imaging plane of the imaging optical system 10 can be switched as long as the X-field-of-view region 1110 or Y-field-of-view region 1120 is positioned relative to light (the optical axis of the imaging optical system 10) from the alignment mark AM1 or AM2 with high accuracy.

However, like the above-mentioned driving unit 40, the driving unit 1200 has a configuration suitable for use under a vacuum environment. It is more difficult for such a driving unit than for a driving unit used under the atmospheric environment to position the field stop 1100 with high accuracy because the former is generally inferior in positioning accuracy. Hence, upon positioning the X-field-of-view region 1110 or Y-field-of-view region 1120, a shift in position occurs with respect to the optical axis of the imaging optical system 10, so light from portions other than the alignment marks enters the detection unit 50 and generates a detection error. Also, when a driving unit used under a vacuum environment is configured to have a performance equivalent to that of a driving unit used under the atmospheric environment, the manufacturing cost becomes very high.

With this arrangement, when the field stop 1100 is driven (the field of view is switched) using a driving unit arranged under a vacuum environment, a shift may occur in positioning of the field stop 1100 due to factors associated with the performance of the driving unit, leading to degradation in detection accuracy of the detection unit 50. Therefore, in the optical device 100, the field of view to be defined on the imaging plane of the imaging optical system 10 is switched using the field stop 20 and light-shielding plate 30, as described above. More specifically, a field stop 20 which requires a large region used to limit the field of view, and high positioning accuracy is fixed to the conjugate plane in the imaging optical system 10. By driving a light-shielding plate 30 which requires a small region used to limit the field of view, and a positioning accuracy lower than that of the field stop 20, the field of view to be defined on the imaging plane of the imaging optical system 10 can be switched without lowering the detection accuracy of the detection unit 50.

FIG. 1C is a view showing the configuration of the field stop 20. The field stop 20 includes an X-field-of-view opening (first aperture) 22 which defines the X field of view (first field of view) on the imaging plane of the imaging optical system 10, and a Y-field-of-view opening (second aperture) 24 which defines the Y field of view (second field of view) on the imaging plane of the imaging optical system 10, as shown in FIG. 1C. Also, the field stop 20 is fixed to the conjugate plane in the imaging optical system 10, and positioned relative to light (the optical axis of the imaging optical system 10) from the alignment mark with high accuracy.

FIG. 1D is a view showing the configuration of the light-shielding plate 30. The light-shielding plate 30 includes an X-field-of-view region (first region) 32 and Y-field-of-view region (second region) 34, as shown in FIG. 1D. The X-field-of-view region 32 includes an X-field-of-view opening region (first aperture region) 32a and light-shielding region (first light-shielding region) 32b, and the Y-field-of-view region 34 includes a Y-field-of-view opening region (second aperture region) 34a and light-shielding region (second light-shielding region) 34b.

In setting the field of view on the imaging plane of the imaging optical system 10, the driving unit 40 drives the light-shielding plate 30 to position the X-field-of-view region 32 or Y-field-of-view region 34. In other words, the driving unit 40 positions the light-shielding plate 30 so as to set one of the X and Y fields of view valid, and partially set the other invalid. In setting, for example, the X field of view on the imaging plane of the imaging optical system 10, the driving unit 40 positions the X-field-of-view region 32 relative to the field stop 20. More specifically, the X-field-of-view region 32 is positioned so that the X-field-of-view opening region 32a does not shield a first path, while the light-shielding region 32b shields a second path. Note that the first path extends from the alignment mark (the object plane of the imaging optical system 10) to the detection unit 50 (the image plane of the imaging optical system 10) through the X-field-of-view opening 22. The second path extends from the alignment mark to the detection unit 50 through the Y-field-of-view opening 24. In this embodiment, the light-shielding plate 30 is arranged on the side of the object plane of the imaging optical system 10 with respect to the field stop 20. Hence, the X-field-of-view opening region 32a passes light, that reaches the X-field-of-view opening 22, of light from the alignment mark, while the light-shielding region 32b shields light, that reaches the Y-field-of-view opening 24, of the light from the alignment mark.

Also, in setting the Y field of view on the imaging plane of the imaging optical system 10, the driving unit 40 positions the Y-field-of-view region 34 relative to the field stop 20. More specifically, the Y-field-of-view region 34 is positioned so that the Y-field-of-view opening region 34a does not shield the second path, while the light-shielding region 34b shields the first path. Hence, the Y-field-of-view opening region 34a passes light, that reaches the Y-field-of-view opening 24, of light from the alignment mark, while the light-shielding region 34b shields light, that reaches the X-field-of-view opening 22, of the light from the alignment mark.

With this arrangement, in the optical device 100 according to this embodiment, the field of view to be defined on the imaging plane of the imaging optical system 10 can be switched by driving the light-shielding plate 30 to position the X-field-of-view region 32 or Y-field-of-view region 34 relative to the field stop 20.

The positioning accuracy of the light-shielding plate 30 driven using the driving unit 40 will be described. The light-shielding plate 30 must implement a function of passing one of light that reaches the X-field-of-view opening 22 and light that reaches the Y-field-of-view opening 24, while shielding the other, as described above. Therefore, the X-field-of-view opening region 32a of the light-shielding plate 30 has a size larger than that of the X-field-of-view opening 22 of the field stop 20, while the Y-field-of-view opening region 34a of the light-shielding plate 30 has a size larger than that of the Y-field-of-view opening 24 of the field stop 20. This makes it possible to set the positioning accuracy required in driving the light-shielding plate 30 lower than that required in driving the field stop 1100 of the optical device 1000. Hence, even if the driving unit 40 has a performance (driving accuracy and stroke) lower than that of a driving unit used under the atmospheric environment, it can position the light-shielding plate 30 with the positioning accuracy required for the light-shielding plate 30.

With this arrangement, in this embodiment, a field stop 20 including a plurality of openings which define the field of view is fixed (not driven), while a light-shielding plate 30 including an opening region which passes light that reaches any of the plurality of openings is driven. This makes it possible to switch the field of view to be defined on the imaging plane of the imaging optical system 10 at low cost and high accuracy without lowering the detection accuracy of the detection unit 50.

The arrangement of the field stop 20 and the light-shielding plate 30 will be described. The field stop 20 need only be fixed to a position, at which the field of view can be limited, such as in the vicinity of the image plane of the imaging optical system 10 or the conjugate plane of this image plane. Also, the light-shielding plate 30 need only be fixed to a position, at which the field of view can be limited by the field stop 20, such as in the vicinity of the field stop 20 or its conjugate plane. The field stop 20 and light-shielding plate 30 are arranged at different positions because of the difference in degree of influence on the detection accuracy of the detection unit 50 upon switching of the field of view. In this embodiment, the field stop 20 fixed to the conjugate plane in the imaging optical system 10 passes light beams corresponding to the X and Y fields of view, and the light-shielding plate 30 shields one of the light beams corresponding to the X and Y fields of view. Note that when, for example, the field stop 20 is arranged at a position other than the conjugate plane in the imaging optical system 10, the range (field-of-view range) of light which passes through the field stop 20 cannot be limited sufficiently, so the light beams corresponding to the X and Y fields of view cannot be guided to the detection unit 50. Hence, the field stop 20 must be arranged on the conjugate plane in the imaging optical system 10 to limit the field-of-view range.

On the other hand, the light-shielding plate 30 need not be arranged on the conjugate plane in the imaging optical system 10 as long as it can shield one of the light beams corresponding to the X and Y fields of view, and no unwanted light incident on the detection unit 50 influences the detection accuracy. The light-shielding plate 30 may be arranged at, for example, a position shifted in the optical axis direction from the conjugate plane in the imaging optical system 10, and shield one of the light beams corresponding to the X and Y fields of view.

However, the amount of shift from the conjugate plane in the imaging optical system 10 at the position at which the light-shielding plate 30 is arranged is determined based on the following elements. The elements include, for example, the distance from the center of each mark on the substrate SB to a reflecting object (unwanted light) other than the marks, the optical magnification between each mark image and the light-shielding plate 30, the sizes of the X-field-of-view opening region 32a and Y-field-of-view opening region 34a of the light-shielding plate 30, and the numerical aperture of light.

Referring to FIGS. 1A and 1B, let dx be the shortest distance from the center of the alignment mark AM1 on the substrate SB to a reflecting object other than the marks, and dy be the shortest distance from the center of the alignment mark AM2 on the substrate SB to a reflecting object other than the marks. Also, let N be the optical magnification between each mark image and the light-shielding plate 30, X be the width of the X-field-of-view opening region 32a, and Y be the width of the Y-field-of-view opening region 34a. Moreover, let xa be the positioning error of the X-field-of-view opening region 32a in the optical axis cross-sectional direction, xb the positioning error of the Y-field-of-view opening region 34a in the optical axis cross-sectional direction, and θ be the angle that light having passed through the field stop 20 makes with the optical axis of the imaging optical system 10. Then, an amount of shift D of the position at which the light-shielding plate 30 is arranged from the conjugate plane in the imaging optical system 10 must satisfy:

D<((X−xa)/2−dx×N)/tan θ (1)

D<((Y−xb)/2−dy×N)/tan θ (2)

When the amount of shift D satisfies inequalities (1) and (2), the light-shielding plate 30 can pass one of the light beams corresponding to the X and Y fields of view, while shielding the other. Note that to determine the tolerance of the amount of shift D, it is necessary to take into consideration errors generated upon, for example, the design and manufacture of an optical system.

Also, in the optical device 100, due, for example, to the constraint of the arrangement space, it is often difficult to arrange the field stop 20 and light-shielding plate 30 on or in the vicinity of the conjugate plane in the imaging optical system 10. In such a case, the field stop 20 need only be arranged (fixed) on one of a plurality of conjugate planes in the imaging optical system 10, while the light-shielding plate 30 is arranged on or in the vicinity of another conjugate plane. In this manner, in the optical device 100, the field stop 20 is arranged on the conjugate plane in the imaging optical system 10, while the light-shielding plate 30 is arranged on or in the vicinity of the conjugate plane in the imaging optical system 10.

In the optical device 100 according to this embodiment, the light-shielding plate 30 is used to pass one of light beams that reach the X-field-of-view opening 22 and Y-field-of-view opening 24 of the field stop 20, while shielding the other, thereby switching the field of view. In other words, the field of view is switched by driving a light-shielding plate 30 which requires a positioning accuracy lower than that of the field stop 20 without driving a field stop 20 which requires high positioning accuracy. Hence, even if a driving unit 40 having a performance lower than that of a driving unit used under the atmospheric environment is used, the field of view can be switched without lowering the detection accuracy of the detection unit 50. Also, since the driving unit 40 need not be configured to have a performance equivalent to that of a driving unit used under the atmospheric environment, an increase in cost can be suppressed.

Although the light-shielding plate 30 is arranged on the side of the object plane of the imaging optical system 10 with respect to the field stop 20 in this embodiment, it may be arranged on the side of the imaging plane of the imaging optical system 10 with respect to the field stop 20. In this case, in setting the X field of view, the X-field-of-view region 32 is positioned so that the X-field-of-view opening region 32a does not shield a first path that extends to the detection unit 50 through the X-field-of-view opening 22, while the light-shielding region 32b shields a second path that extends to the detection unit 50 through the Y-field-of-view opening 24. Hence, the X-field-of-view opening region 32a passes light having passed through the X-field-of-view opening 22, while the light-shielding region 32b shields light having passed through the Y-field-of-view opening 24. Also, in setting the Y field of view, the Y-field-of-view region 34 is positioned so that the Y-field-of-view opening region 34a does not shield a second path that extends to the detection unit 50 through the Y-field-of-view opening 24, while the light-shielding region 34b shields a first path that extends to the detection unit 50 through the X-field-of-view opening 22. Hence, the Y-field-of-view opening region 34a passes light having passed through the Y-field-of-view opening 24, while the light-shielding region 34b shields light having passed through the X-field-of-view opening 22.

Also, although the light-shielding plate 30 has both the X-field-of-view region 32 and Y-field-of-view region 34 in this embodiment, the present invention is not limited to this. In place of the light-shielding plate 30, a plurality of light-shielding members including a first light-shielding member having the X-field-of-view region 32, and a second light-shielding member having the Y-field-of-view region 34, for example, may be independently driven. Alternatively, a plurality of blades may constitute a light-shielding plate, and be independently driven to form the X-field-of-view region 32 (light-shielding region 32b) or Y-field-of-view region 34 (light-shielding region 34b).

### Second Embodiment

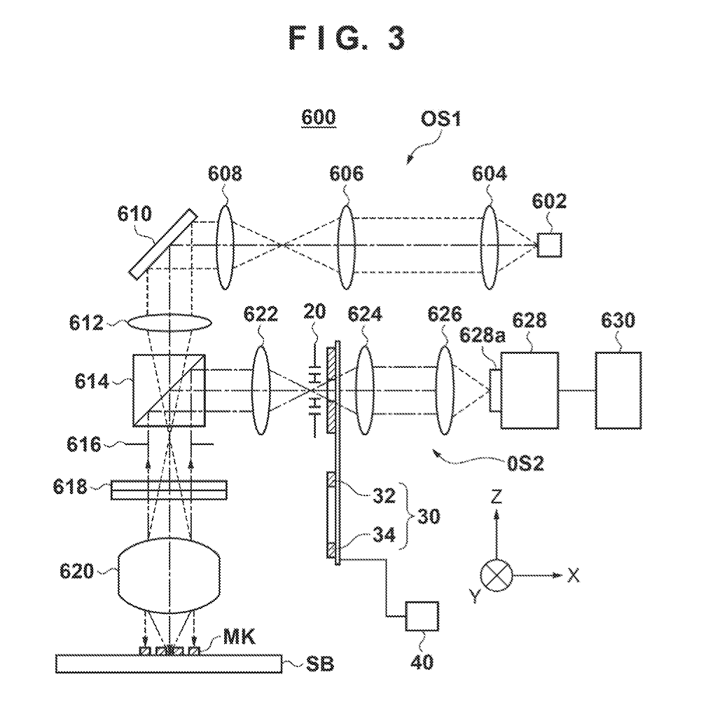

FIG. 3 is a view showing the configuration of a position detection apparatus (measuring apparatus) 600 according to an aspect of the present invention. The position detection apparatus 600 includes an illumination optical system OS1 which illuminates a substrate SB (mark MK) with light from a light source 602, an imaging optical system OS2 which forms an image of the light from the mark MK on a detection unit 628, and a processing unit 630 which obtains the position of the substrate SB (mark MK). The mark MK formed on the substrate SB includes X and Y alignment marks.

The illumination optical system OS1 includes illumination lenses 604, 606, and 608, mirror 610, illumination lens 612, polarizing beam splitter 614, aperture stop 616, λ/4 plate 618, and objective lens 620. The imaging optical system OS2 includes the objective lens 620, the λ/4 plate 618, the aperture stop 616, the polarizing beam splitter 614, a lens 622, a field stop 20, a light-shielding plate 30, and lenses 624 and 626.

In the position detection apparatus 600, light from the light source 602 is guided to the polarizing beam splitter 614 via the illumination lenses 604, 606, and 608, mirror 610, and illumination lens 612. The polarizing beam splitter 614 transmits P-polarized light parallel to the Y-axis, and reflects S-polarized light parallel to the X-axis. The P-polarized light transmitted through the polarizing beam splitter 614 is guided to the λ/4 plate 618 via the aperture stop 616. Light converted into circularly polarized light upon passing through the λ/4 plate 618 illuminates the mark MK, formed on the substrate SB, via the objective lens 620.

Light reflected, diffracted, and scattered by the mark MK is converted from circularly polarized light into S-polarized light upon passing through the objective lens 620 and λ/4 plate 618, and reaches the aperture stop 616. Note that light which leaves the mark MK is circularly polarized in a direction opposite to that of circularly polarized light which illuminates the mark MK. In other words, if light which illuminates the mark MK is clockwise circularly polarized light, light which leaves the mark MK is counterclockwise circularly polarized light. Also, the numerical aperture of light from the mark MK can be controlled by changing the aperture value of the aperture stop 616. Light having passed through the aperture stop 616 is reflected by the polarizing beam splitter 614, and guided to the detection unit 628 via the lens 622, field stop 20, light-shielding plate 30, and lenses 624 and 626. Hence, an image of the mark MK formed on the substrate SB is formed on a detection surface 628a of the detection unit 628. The processing unit 630 obtains the position of the mark MK, that is, the position of the substrate SB based on the image of the mark MK detected by the detection unit 628.

In the position detection apparatus 600 according to this embodiment, the light-shielding plate 30 is used to pass one of light beams that reach an X-field-of-view opening 22 and Y-field-of-view opening 24 of the field stop 20, while shielding the other. When, for example, an X-field-of-view region 32 of the light-shielding plate 30 is positioned relative to the field stop 20, the light-shielding plate 30 passes light having passed through the X-field-of-view opening 22 of the field stop 20, while shielding light having passed through the Y-field-of-view opening 24 of the field stop 20. With this operation, the detection unit 628 can detect an image of the X alignment mark of the mark MK formed on the substrate SB. Also, when a Y-field-of-view region 34 of the light-shielding plate 30 is positioned relative to the field stop 20, the light-shielding plate 30 passes light having passed through the Y-field-of-view opening 24 of the field stop 20, while shielding light having passed through the X-field-of-view opening 22 of the field stop 20. With this operation, the detection unit 628 can detect an image of the Y alignment mark of the mark MK formed on the substrate SB.

With this arrangement, in the position detection apparatus 600 according to this embodiment, the field of view is switched by driving a light-shielding plate 30 which requires a positioning accuracy lower than that of the field stop 20 without driving a field stop 20 which requires high positioning accuracy. Hence, even if a driving unit 40 having a performance lower than that of a driving unit used under the atmospheric environment is used, the field of view can be switched without lowering the accuracy of the field-of-view region. This makes it possible to suppress degradation in accuracy of detection of the mark MK by the detection unit 628. In other words, the position detection apparatus 600 can detect the mark MK with high accuracy to, in turn, detect the position of the substrate SB (the position of the mark MK) with high accuracy. Also, since the driving unit 40 need not be configured to have a performance equivalent to that of a driving unit used under the atmospheric environment, an increase in cost can be suppressed.

Although the field stop 20, light-shielding plate 30, and driving unit 40 are included in the imaging optical system OS2 in this embodiment, they may be included in the illumination optical system OS1. In this case, the light-shielding plate 30 is used to pass one of light beams which are emitted by the light source 602 and pass through the X-field-of-view opening 22 and Y-field-of-view opening 24 of the field stop 20, while shielding the other, thereby switching the field of view (illumination field of view) in which the mark MK is illuminated. In other words, the field stop 20 functions as an illumination field stop to switch the detection conditions under which the mark MK is detected by the detection unit 628 (detection surface 628a). Even if the illumination optical system OS1 includes the field stop 20 and light-shielding plate 30, the illumination field of view can be switched by driving a light-shielding plate 30 which requires a positioning accuracy lower than that of the field stop 20 without driving a field stop 20 which requires high positioning accuracy.

In setting the illumination field of view to, for example, the X field of view, the driving unit 40 positions the X-field-of-view region 32 of the light-shielding plate 30 relative to the field stop 20. More specifically, the X-field-of-view region 32 is positioned so that an X-field-of-view opening region 32a does not shield a path that extends from a light source 402 to the mark MK through the X-field-of-view opening 22, while a light-shielding region 32b shields a path that extends from the light source 402 to the mark MK through the Y-field-of-view opening 24. With this operation, the detection unit 628 can detect an image of the X alignment mark of the mark MK formed on the substrate SB.

Also, in setting the illumination field of view to the Y field of view, the driving unit 40 positions the Y-field-of-view region 34 of the light-shielding plate 30 relative to the field stop 20. More specifically, the Y-field-of-view region 34 is positioned so that a Y-field-of-view opening region 34a does not shield a path that extends from the light source 402 to the mark MK through the Y-field-of-view opening 24, while a light-shielding region 34b shields a path that extends from the light source 402 to the mark MK through the X-field-of-view opening 22. With this operation, the detection unit 628 can detect an image of the Y alignment mark of the mark MK formed on the substrate SB.

### Third Embodiment

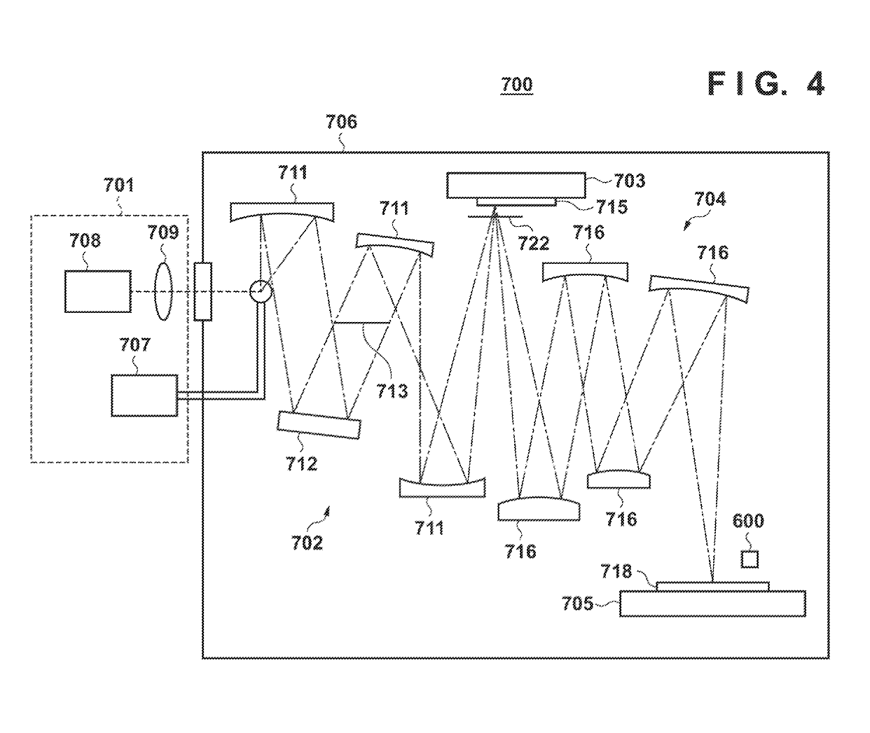

FIG. 4 is a view showing the configuration of an exposure apparatus 700 to which a position detection apparatus 600 is applied. The exposure apparatus 700 serves as a lithography apparatus which transfers the pattern of a reticle onto a substrate (for example, a wafer), that is, patterns the substrate with EUV (Extreme Ultra Violet) light having a wavelength of about 10 to 15 nm.

The exposure apparatus 700 includes a light source unit 701, illumination optical system 702, reticle stage 703, projection optical system 704, substrate stage 705, and vacuum chamber 706. The vacuum chamber 706 accommodates the illumination optical system 702, reticle stage 703, projection optical system 704, and substrate stage 705. Also, the interior of the vacuum chamber 706 is maintained in a vacuum environment with a high pressure that falls within the range of, for example, 10⁻⁴ to 10⁻⁵ Pa.

The light source unit 701 includes a target supply unit 707, excitation pulsed laser irradiation unit 708, and condenser lens 709. The light source unit 701 emits a pulsed laser beam from the excitation pulsed laser irradiation unit 708 to a target material, which is supplied from the target supply unit 707 to the vacuum chamber 706, via the condenser lens 709 to generate a plasma 710 which radiates EUV light.

The illumination optical system 702 includes a plurality of mirrors 711 including, for example, a multilayer mirror and grazing-incidence mirror, an optical integrator 712, and an aperture 713. The illumination optical system 702 focuses EUV light radiated from the plasma 710 to illuminate a reticle 715 held on the reticle stage 703.

The projection optical system 704 includes a plurality of mirrors 716 and an aperture 722, and projects EUV light reflected by the reticle 715 onto a substrate 718 held on the substrate stage 705. The substrate stage 705 functions as a positioning mechanism which positions the substrate 718 in cooperation with a control unit which controls the overall exposure apparatus 700.

The exposure apparatus 700 can employ the position detection apparatus 600 to position the reticle 715 and the substrate 718 relative to each other, and position a plurality of shot regions on the substrate 718 relative to each other. The position detection apparatus 600 can detect the position of the substrate 718 and that of each shot region on the substrate 718 with high accuracy, as described above. Hence, since the exposure apparatus 700 can position the reticle 715 and the substrate 718 relative to each other, and position a plurality of shot regions on the substrate 718 relative to each other with high accuracy, it can transfer the pattern of the reticle 715 onto the substrate 718 with high accuracy.

### Fourth Embodiment

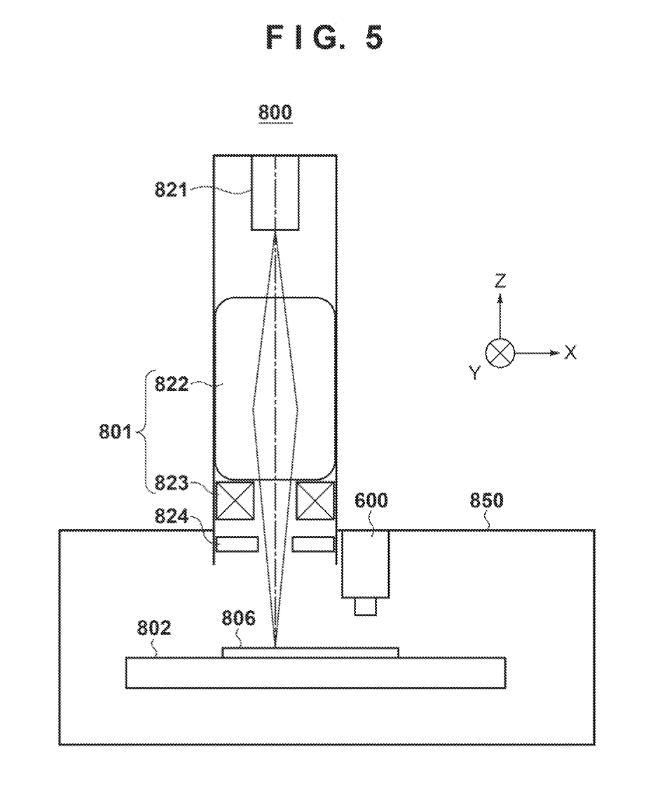

FIG. 5 is a view showing the configuration of a drawing apparatus 800 to which a position detection apparatus 600 is applied. The drawing apparatus 800 serves as a lithography apparatus which draws a pattern on a substrate, that is, patterns the substrate with a charged particle beam (electron beam).

The drawing apparatus 800 includes an electron gun 821, a charged particle optical system 801, a detection system 824 which detects a charged particle beam, a substrate stage 802 which holds a substrate 806, and a vacuum chamber 850. The vacuum chamber 850 accommodates the electron gun 821, charged particle optical system 801, detection system 824, and substrate stage 802. The charged particle optical system 801 includes a charged particle lens 822 which converges a charged particle beam from the electron gun 821, and a deflector 823 which deflects the charged particle beam. The substrate stage 802 functions as a positioning mechanism which positions the substrate 806 in cooperation with a control unit which controls the overall drawing apparatus 800.

The drawing apparatus 800 can employ the position detection apparatus 600 to position the charged particle beam and the substrate 806 relative to each other, and position a plurality of shot regions on the substrate 806 relative to each other. The position detection apparatus 600 can detect the position of the substrate 806 and that of each shot region on the substrate 806 with high accuracy, as described above. Hence, since the drawing apparatus 800 can position the charged particle beam and the substrate 806 relative to each other, and position a plurality of shot regions on the substrate 806 relative to each other with high accuracy, it can draw a pattern on the substrate 806 with high accuracy.

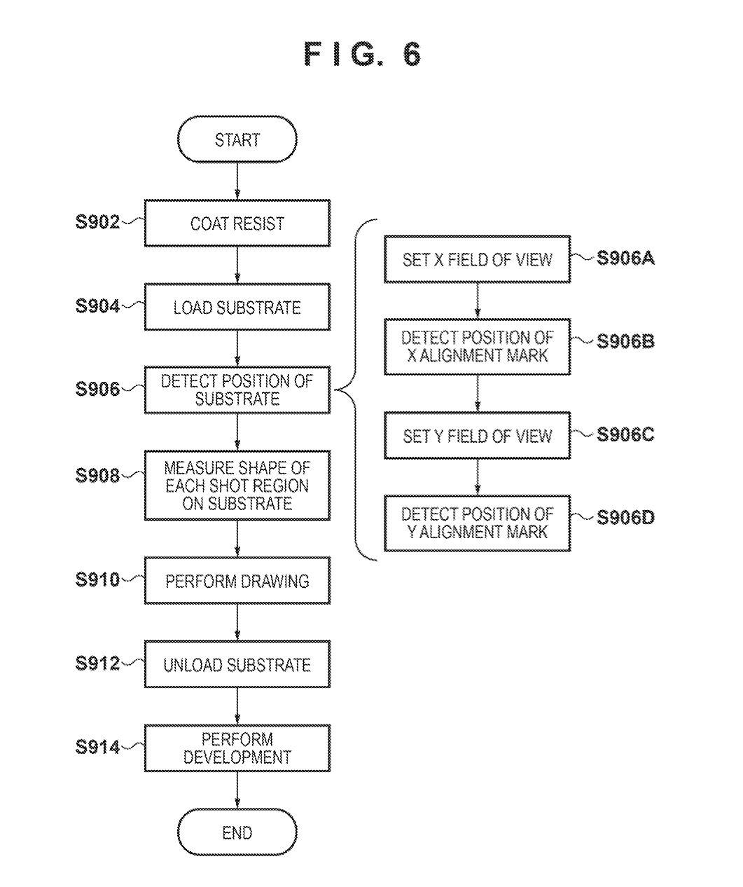

FIG. 6 is a flowchart for explaining a drawing process by the drawing apparatus 800. In step S902, a resist (photosensitive agent) is applied (supplied) onto a substrate 806 by a resist coating device. In step S904, the substrate 806 coated with the resist is loaded into the drawing apparatus 800 (vacuum chamber 850), and set on the substrate stage 802. In step S906, the position of the substrate 806 set on the substrate stage 802 is detected using the position detection apparatus 600. In step S908, the shapes of a plurality of shot regions on the substrate 806 are measured using a shape measuring device. In step S910, a pattern is drawn on the substrate 806 while positioning the charged particle beam and the substrate 806 relative to each other, and positioning a plurality of shot regions on the substrate 806 relative to each other, based on the detection result (step S906) obtained by the position detection apparatus 600, and the measurement result (step S908) obtained by the shape measuring device. In step S912, the substrate 806 having the pattern drawn on it is unloaded from the drawing apparatus 800 (vacuum chamber 850). In step S914, the substrate 806 having the pattern drawn on it is developed by a developing device.

In step S906, the position detection apparatus 600 sequentially detects the X and Y alignment marks formed in a plurality of shot regions on the substrate 806. More specifically, in step S906A, an X-field-of-view region 32 of a light-shielding plate 30 is positioned relative to a field stop 20 to set the X field of view. In step S906B, the position of the X alignment mark is detected while the X field of view is set. In step S906C, a Y-field-of-view region 34 of the light-shielding plate 30 is positioned relative to the field stop 20 to set the Y field of view. In step S906D, the position of the Y alignment mark is detected while the Y field of view is set.

### Fifth Embodiment

A method of manufacturing an article according to an aspect of the present invention is suitable for manufacturing various articles including a microdevice such as a semiconductor device and an element having a microstructure. A method of manufacturing an article according to this embodiment includes a step of transferring a pattern (latent image pattern) on a resin, coated on a substrate, using an exposure apparatus 700 or a drawing apparatus 800, and a step of developing (processing) the substrate having the pattern transferred onto it in the transferring step. This method can also include subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional method.

Aspects of the present invention can also be realized by a computer of a system or apparatus (or devices such as a CPU or MPU) that reads out and executes a program recorded on a memory device to perform the functions of the above-described embodiments, and by a method, the steps of which are performed by a computer of a system or apparatus by, for example, reading out and executing a program recorded on a memory device to perform the functions of the above-described embodiments. For this purpose, the program is provided to the computer for example via a network or from a recording medium of various types serving as the memory device (for example, computer-readable medium).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-084701 filed on Apr. 3, 2012, which is hereby incorporated by reference herein in its entirety.

What is claimed is:

1. An optical apparatus which detects an image of a mark on a substrate, the apparatus comprising:
an optical system configured to form an image of the mark;
a detector configured to detect the image, wherein the optical system includes an aperture stop, an aperture, corresponding to a first field of view and a second field of view of the detector, being formed in the aperture stop;
a light-shielding member; and
a driving mechanism configured to position the light-shielding member so that one of the first field of view and the second field of view is valid, and a part of the other is invalid.

2. The apparatus according to claim 1, wherein the aperture stop includes a field stop.

3. The apparatus according to claim 1, wherein
the optical system includes an imaging optical system configured to form an image of the mark, and an illumination optical system configured to illuminate the mark, and
the aperture stop includes an illumination field stop.

4. The apparatus according to claim 1, wherein
the light-shielding member includes a first light-shielding region and a second light-shielding region, and
the driving mechanism is configured to position the light-shielding member so that a part of the second field of view is invalid with the first light-shielding region if the first field of view is to be valid, and to position the light-shielding member so that a part of the first field of view is invalid with the second light-shielding region if the second field of view is to be valid.

5. The apparatus according to claim 4, wherein in the light-shielding member, a first aperture region is formed to be surrounded by the first light-shielding region so that the first field of view is valid, and a second aperture region is formed to be surrounded by the second light-shielding region so that the second field of view is valid.

6. The apparatus according to claim 1, wherein
the light-shielding member includes a first light-shielding member and a second light-shielding member, and
the driving mechanism is configured to position the first light-shielding member so that the second field of view is invalid with the first light-shielding member if the first field of view is to be valid, and to position the second light-shielding member so that the first field of view is invalid with the second light-shielding member if the second field of view is to be valid.

7. The apparatus according to claim 1, wherein at least the driving mechanism is arranged under a vacuum environment.

8. A measuring apparatus comprising:
an optical apparatus configured to detect an image of a mark on a substrate; and
a processor configured to obtain a position of the mark based on the detected image,
wherein the optical device includes:
an optical system configured to form an image of the mark;
a detector configured to detect the image, wherein the optical system includes an aperture stop, an aperture, corresponding to a first field of view and a second field of view of the detector, being formed in the aperture stop;
a light-shielding member; and
a driving mechanism configured to position the light-shielding member so that one of the first field of view and the second field of view is valid, and a part of the other is invalid.

9. A lithography apparatus which patterns a substrate, the apparatus comprising:
a measuring apparatus configured to measure a position of a mark on a substrate; and
a positioning mechanism configured to position the substrate based on the measured position,
wherein the measuring apparatus includes:
an optical apparatus configured to detect an image of a mark on a substrate; and
a processor configured to obtain a position of the mark based on the detected image,
wherein the optical apparatus includes:
an optical system configured to form an image of the mark;
a detector configured to detect the image, wherein the optical system includes an aperture stop, an aperture, corresponding to a first field of view and a second field of view of the detector, being formed in the aperture stop;
a light-shielding member; and
a driving mechanism configured to position the light-shielding member so that one of the first field of view and the second field of view is valid, and a part of the other is invalid.

10. A method of manufacturing an article, the method comprising:
patterning a substrate using a lithography apparatus; and
processing the patterned substrate to manufacture the article,
wherein the lithography apparatus includes:
a measuring apparatus configured to measure a position of a mark on a substrate; and
a positioning mechanism configured to position the substrate based on the measured position,
wherein the measuring apparatus includes:
an optical apparatus configured to detect an image of a mark on a substrate; and
a processor configured to obtain a position of the mark based on the detected image,
wherein the optical apparatus includes:
an optical system configured to form an image of the mark;
a detector configured to detect the image, wherein the optical system includes an aperture stop, an aperture, corresponding to a first field of view and a second field of view of the detector, being formed in the aperture stop;
a light-shielding member; and
a driving mechanism configured to position the light-shielding member so that one of the first field of view and the second field of view is valid, and a part of the other is invalid.
